(19) United States
(12) Patent Application Publication
(10) Pub. No.: US 2015/0041731 A1
(43) Pub. Date: Feb. 12, 2015

(54) Method For Preparing Scandium-Doped Hafnium Oxide Film

(71) Applicant: Chung-Shan Institute of Science and Technology Armaments Bureau, Ministry of National Defense, Taoyuan County (TW)

(72) Inventors: Yi-Lung Tsai, Taoyuan County (TW); Hui-Yun Bor, Taoyuan County (TW); Chao-Nan Wei, Taoyuan County (TW); Yuan-Pang Wu, Taoyuan County (TW); Sea-Fue Wang, Taoyuan County (TW); Hong-Syuan Chen, Taoyuan County (TW)

(73) Assignee: Chung-Shan Institute of Science and Technology Armaments Bureau, Ministry of National Defense, Taoyuan County (TW)

(21) Appl. No.: 13/963,181

(22) Filed: Aug. 9, 2013

(51) Int. Cl. H01L 21/02; H01L 29/06

(52) U.S. Cl. CPC H01L 21/02181; H01L 21/02266; H01L 29/0649
USPC 252/518.1; 204/192.1

(57) ABSTRACT

A method for preparing scandium-doped hafnium oxide film includes preparing a hafnium target having scandium granules distributed on a peripheral surface thereof; and proceeding a sputtering process to form a scandium-doped hafnium oxide film on a substrate, wherein the scandium doping of the scandium-doped hafnium oxide film is in the range of 3-13%. Such scandium-doped hafnium oxide film is able to be used as an oxide layer in semiconductor element which effectively suppresses the current leakage and reduces the dimension of the semiconductor element.

### BACKGROUND OF THE INVENTION

1. Field of the Invention

This invention is related to a method for preparing a hafnium oxide film, and more particularly to a hafnium oxide film with scandium doped therein.

2. Description of the Related Art

As the technology becomes more advanced, dimensions of electric elements are progressively reduced. For example, silicon dioxide (SiO₂), a conventional material, is normally used for oxide layer within an integrated circuit (IC) as an insulator. However, the greatest drawback encountered during the thinning process of the silicone dioxide is that the current leakage is exponentially increased while the thickness of the oxide layer is reduced, which deteriorates electron loss situation in the channel and lowering the driving capability as well as capacitance effect among micro-electronic elements.

To overcome the current leakage in the reduced IC, materials with high K are used as the oxide layer for its great thickness. One of the high K materials is hafnium oxide (HfO₂), which has a large band gap and a good lattice match with silicon substrate. However, there are some problems with the hafnium oxide layer when applied in transistors. The physical feature of the hafnium oxide layer is possibly affected by the working voltage of the transistor because of the lattice defect of the hafnium oxide, the thickness of the hafnium oxide layer and the potential energy difference between the contact face of the hafnium oxide layer and either the metal or the semiconductor. Moreover, under the conditions where the thickness of the hafnium oxide layer is thinned, many effects like Schottky Emission effect, Tunneling effect, Poole-Frenkel effect, internal Schottky Emission effect, and Space-Charge Limited Current effect are taking place in the hafnium oxide layer to cause the leak. Hence, how to enhance the hafnium oxide layer to prevent the current leakage is expected.

### SUMMARY OF THE INVENTION

The primary purpose of the present invention is to provide an oxide layer for electric elements, such as IC, which prevents current leakage current leakage to enhance the efficiency of electronic elements.

In order to accomplish the aforementioned purpose, an oxide layer, scandium-doped hafnium oxide film is prepared by a method including:

preparing a hafnium target having scandium granules distributed on a peripheral surface thereof; and

proceeding a sputtering process to form a scandium-doped hafnium oxide film on a substrate, wherein pressure of the sputtering process is under 5×10⁻⁷ torr, working pressure of the sputtering process is 1×10⁻² torr, flow ratio of argon and oxygen of the sputtering process is 1:1, sputtering power of the sputtering process is 100 W and the sputtering process is proceeded for 20 minutes, range of scandium doping in the scandium-doped hafnium oxide film is 3-13 at %, and thickness of the scandium-doped hafnium oxide film is reduced while the scandium doping is increased. Such that, the scandium-doped hafnium oxide film used as the oxide layer in the electronic element is not only to prevent current leakage but reduce the dimension of the electronic element by controlling the scandium doping.

### BRIEF DESCRIPTION OF THE DRAWINGS

The invention, as well as its many advantages, may be further understood by the following detailed description and drawings in which:

FIG. 1 is a plan view showing the hafnium target with the sputtering area, for preparing the scandium-doped hafnium oxide film by the method constructed in accordance with the preferred embodiment of the present invention;

FIG. 2 is a plan view showing the hafnium target with scandium granules distributed on the sputtering area of FIG. 1, for preparing the scandium-doped hafnium oxide film by the method constructed in accordance with the preferred embodiment of the present invention;

FIG. 3 illustrates a chart of X-ray diffraction analysis to products prepared by the method constructed in accordance with the preferred embodiment of the present invention;

FIG. 4 illustrates a chart showing the relationship between the scandium doping (%) and the occupation ratio (%) of the scandium granules to the sputtering area of the hafnium target;

FIGS. 5-13 are SEM cross-sectional views respectively showing the scandium-doped hafnium oxide film prepared by the method constructed in accordance with the preferred embodiment of the present invention;

FIG. 14 is an application showing a metal-insulator-metal (MIM) capacitance including the scandium-doped hafnium oxide layer prepared by the method constructed in accordance with the preferred embodiment of the present invention;

FIG. 15 is a chart showing the relationship between the current leakage and the electric field in the different scandium-doped MIM capacitances; and

FIG. 16 is a chart showing the relationship between the dielectric constant and the scandium doping (%) in the different scandium-doped MIM capacitances.

### DETAILED DESCRIPTION OF THE INVENTION

A method for preparing scandium-doped hafnium oxide film constructed in accordance with the preferred embodiment of the present invention includes steps as follows.

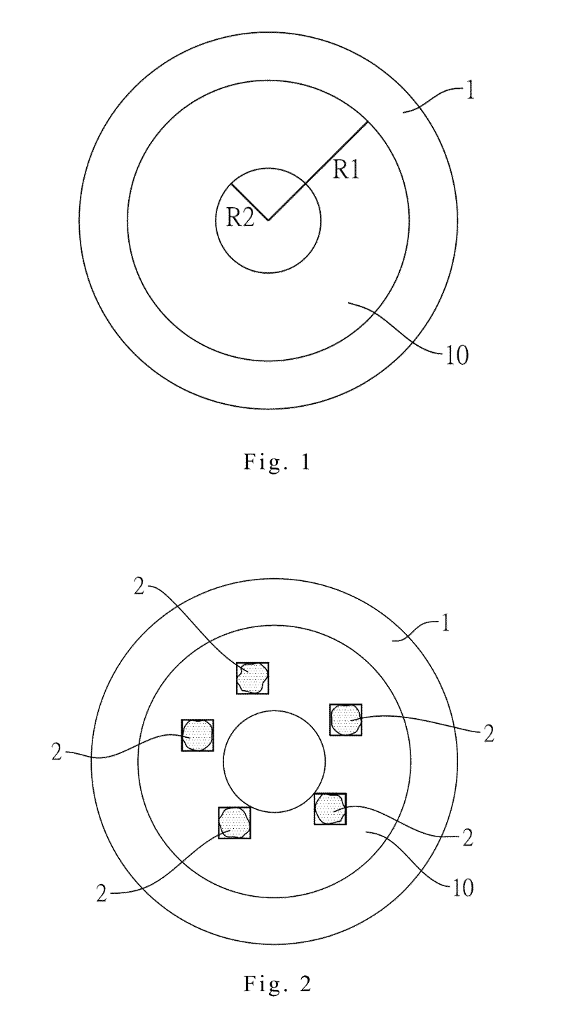

First of all, a target having hafnium and scandium is prepared for sputtering deposition process. With reference to FIG. 1, a hafnium target 1 has a sputtering area 10 defined on the peripheral surface of the hafnium target 1. The sputtering area 10 is defined by (R₁)²π-(R₂)²π, wherein R₁ is a radius of the hafnium target 1 and R₂ is a radius of an area near the center of the hafnium target 1. With reference to FIG. 2, the hafnium target 1 further has scandium granules 2 secured on the sputtering area 10 by silver adhesive. Each of scandium granules 2 is considered as a cube, and the occupation ratio of scandium granules 2 to the sputtering area 10 is defined by a square of the cube/the sputtering area 10 (%). In the preferred embodiment of the present invention, the occupation ratio is 3.50-38.20%.

After the scandium-hafnium target is prepared, a DC magnetron sputtering process is processed. A cleaned substrate, such as silicon substrate, is provided and the cleaned substrate and the scandium-hafnium target are placed in a chamber of a DC magnetron sputtering system (not shown) which is an apparatus well know in the art and thus the configuration as well as the operation thereof are omitted for brevity. The DC magnetron sputtering system includes a rotary oil-sealed pump and a turbo-molecular pump to pump the air out of the chamber respectively, and the pressure in the chamber is reduced to a value under 5×10⁻² torr by the rotary oil-sealed pump. Then the pressure in the chamber is further reduced to a value under 5×10⁻⁶ torr by the turbo-molecular pump. After that, argon gas is added into the chamber to adjust the pressure to 5×10⁻³ torr and this value is maintained for 10 minutes. Then operating parameters to the DC magnetron sputtering system are determined for proceeding a sputtering process for 20 minutes, in which the base pressure is under 5×10⁻⁷ torr, the working pressure is 1×10⁻² torr, the gas flow ratio of argon and oxygen in the chamber is 1:1 and the sputtering power is 100 W. After the sputtering process is finished, a scandium-doped hafnium oxide film is formed on the substrate.

In the step of preparing the scandium-hafnium target, the ratio of the scandium granules 2 and the sputtering area 10 is a factor to control the scandium doping of the scandium-doped hafnium. With reference to Tab. 1, which shows nine scandium-hafnium targets (samples 1-9) with different ratios (the scandium granule/the sputtering area %). The samples 1-9 are able to be used to form the scandium-doped hafnium oxide films (products 1-9) on the substrate by the method constructed in accordance with the preferred embodiment of the invention, as shown in Tab. 2 which is measured by an electron probe X-ray micro analyzer (EPMA).

| | | Ratio of scandium |
|---|---|---|
| | Number of the | granule(s) to the |
| Sc/Hf target | scandium granule | sputtering area (%) |
| sample 1 | 1 | 3.50 |
| sample 2 | 2 | 6.90 |
| sample 3 | 3 | 10.40 |
| sample 4 | 4 | 13.90 |
| sample 5 | 5 | 17.30 |
| sample 6 | 6 | 20.80 |
| sample 7 | 7 | 22.92 |
| sample 8 | 9 | 30.57 |
| sample 9 | 11 | 38.20 |

Tab. 1 shows the scandium-hafnium targets with different number of the scandium granule and the ratio of granule(s) to the sputtering area.

| Product | Hafnium (at %) | Oxygen (at %) | Scandium((at %)) |
|---|---|---|---|
| 1 | 36.88 | 61.67 | 1.45 |
| 2 | 34.87 | 62.20 | 2.93 |
| 3 | 36.55 | 59.45 | 3.99 |
| 4 | 35.43 | 59.35 | 5.22 |
| 5 | 34.48 | 59.56 | 5.96 |
| 6 | 34.42 | 58.63 | 6.95 |
| 7 | 25.40 | 65.04 | 9.57 |
| 8 | 22.71 | 64.46 | 12.83 |
| 9 | 24.10 | 59.77 | 16.12 |

Tab. 2 shows atomic percentage of each of element in the different scandium-doped hafnium oxide films (products 1-9).

To compare the physical feature of the scandium-doped hafnium oxide films with different scandium doping, analyses such as the composition, contents and the thickness of different scandium-doped hafnium oxide films are made as follows.

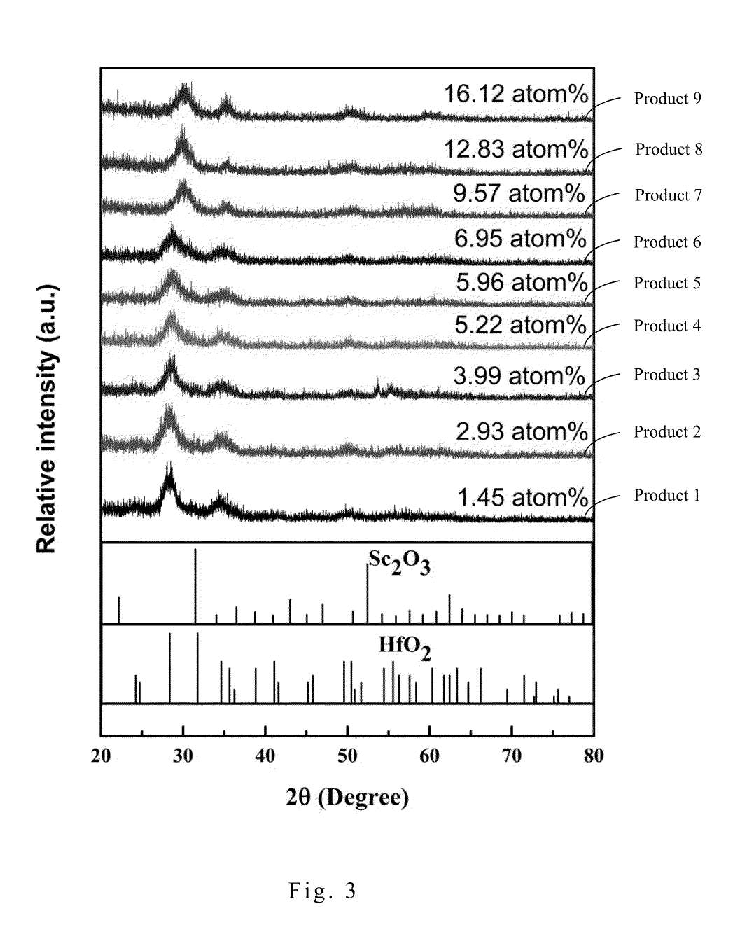

With reference to FIG. 3, which shows an X-ray diffraction analysis to the different scandium-doped hafnium oxide films (products 1-9) and shows a standard x-ray diffraction result of discandium trioxide (Sc₂O₃) and hafnium oxide (HfO₂) which is made in accordance with No. 05-0629 and No. 06-0318 from a data base of Joint Committee on Powder Diffraction Standards (JCPDS). As shown in FIG. 3, the analyzed data of the different scandium-doped hafnium oxide films respectively has a peak corresponding to the peaks of the x-ray diffraction result of Sc₂O₃ and HfO₂, which means the scandium is positively doped within the hafnium oxide film.

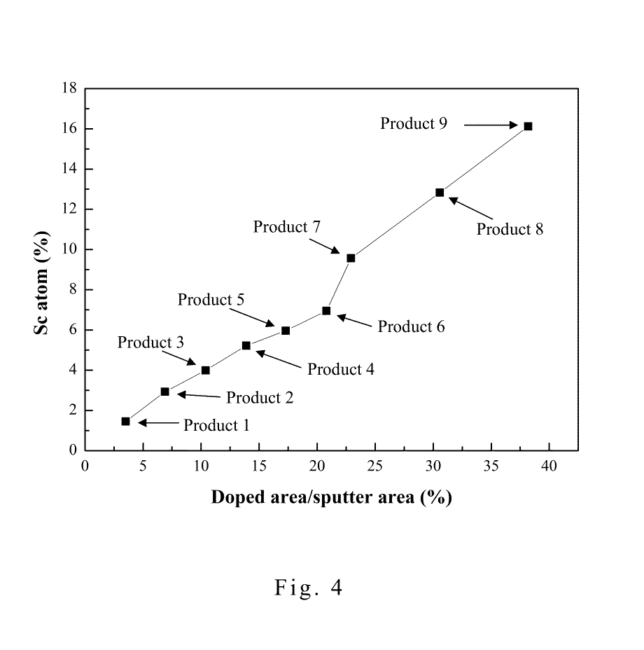

With reference to FIG. 4, a diagram shows a nearly proportional relationship between the scandium doping in products 1-9 and the scandium granules in the samples 1-9. That is, while the scandium doping in products 1-9 is increased, ratio of the scandium granules in the samples 1-9 is also increased.

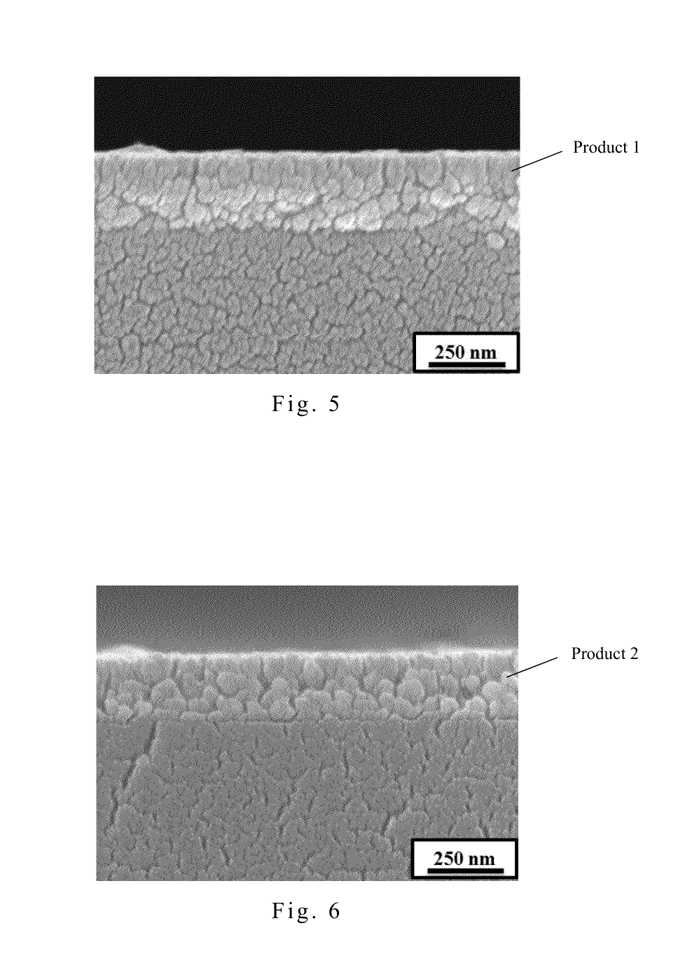

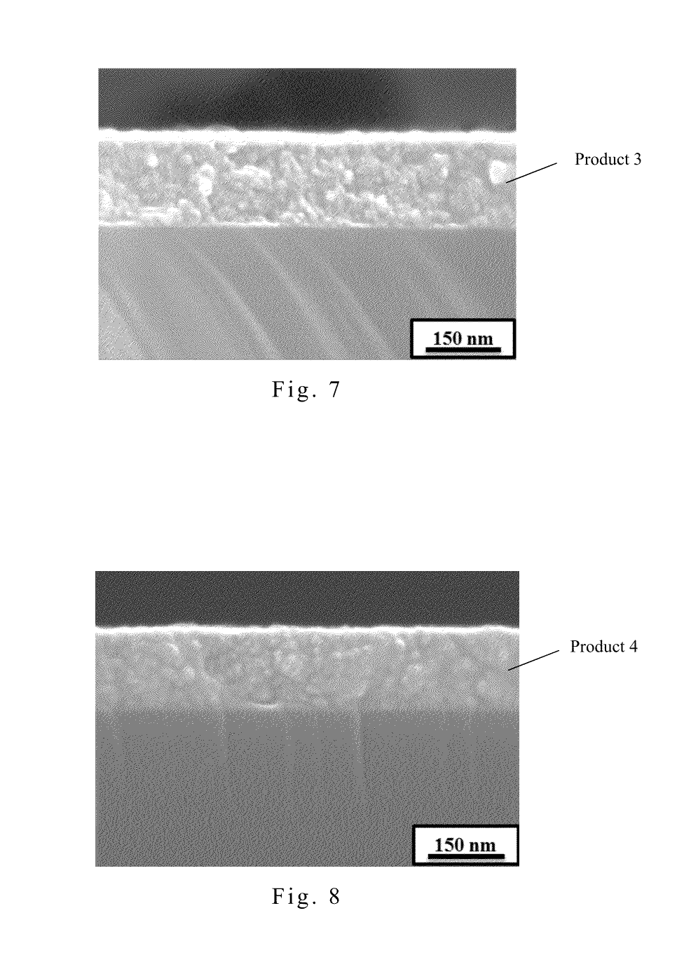

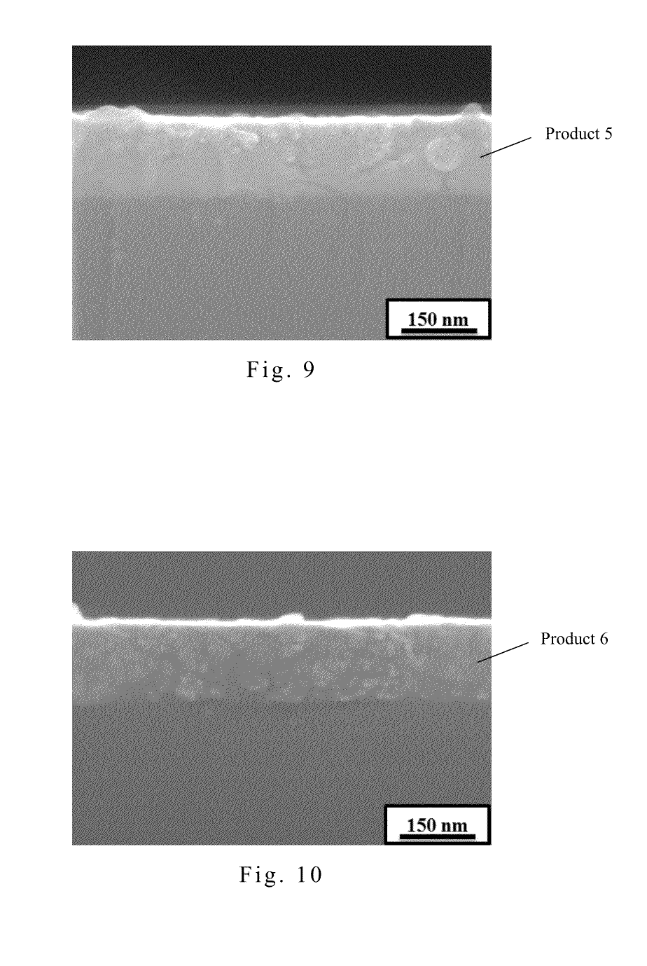

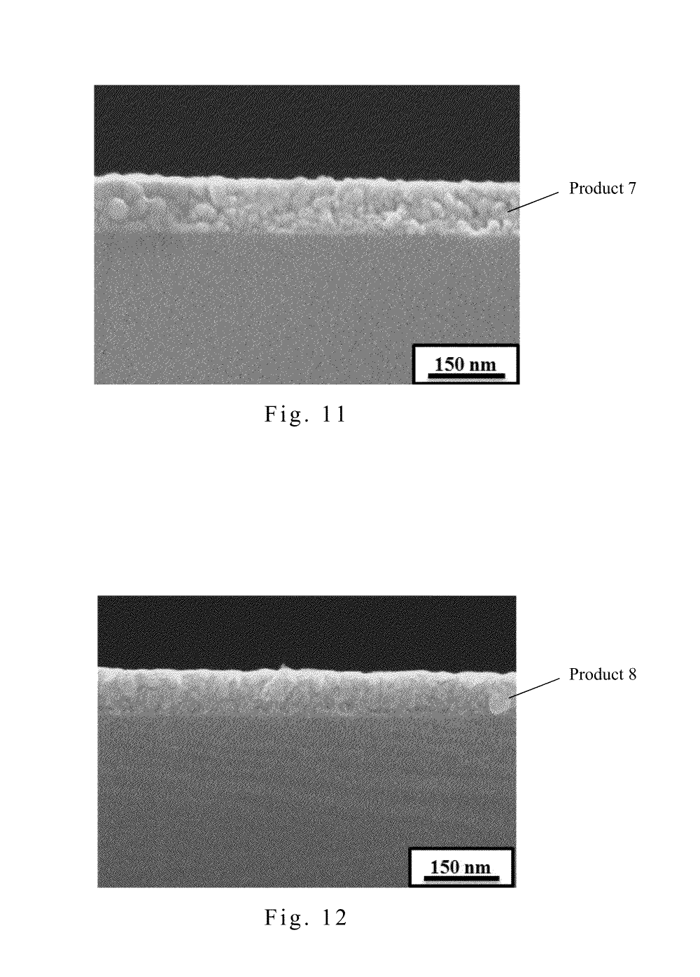

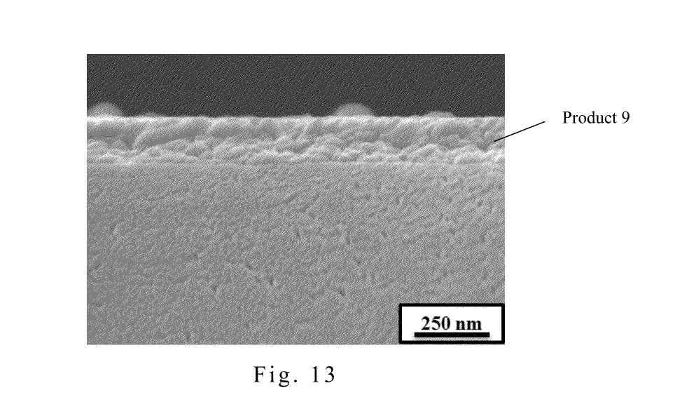

With reference to Figs.5-13 and Tab. 3, an analysis to the thickness of different scandium-doped hafnium oxide films (products 1-9) by a high resolution field-emission scanning electron microscope (SEM) is shown. Tab. 3 shows a relationship between the scandium doping and the corresponding thickness, and the relationship is proportional to the products 1-8, that the thickness of the scandium-doped hafnium oxide film is reduced while the scandium doping is increased.

| | | Thickness of the |
|---|---|---|
| | | scandium-doped hafnium |
| Product | Scandium doping (at %) | oxide film (nm) |
| 1 | 1.45 | 233 |
| 2 | 2.93 | 200 |
| 3 | 3.99 | 169 |
| 4 | 5.22 | 159 |
| 5 | 5.96 | 159 |
| 6 | 6.95 | 159 |
| 7 | 9.57 | 125 |
| 8 | 12.83 | 118 |
| 9 | 16.12 | 133 |

Tab. 3 shows a relation between the scandium doping and the product thickness.

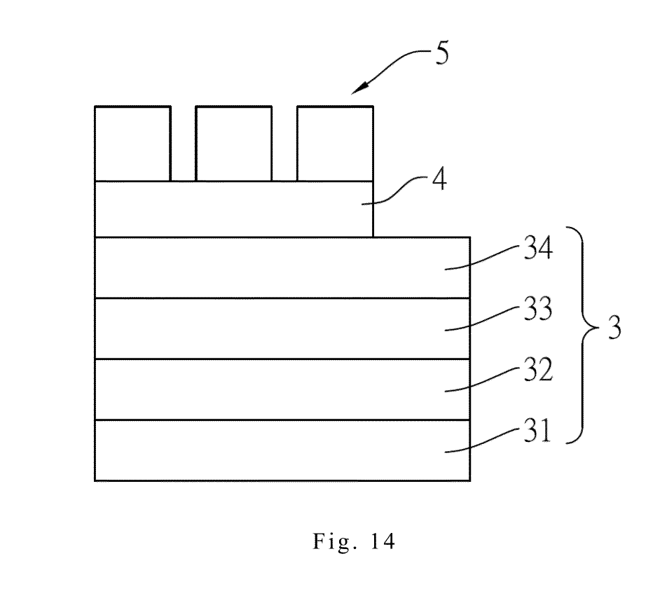

With reference to FIG. 14, a structure of a metal-insulator-metal (MIM) capacitance includes a first electrode 3, a scandium-doped hafnium oxide layer 4 formed on the first electrode 3 by the method constructed in accordance with the preferred embodiment of the present invention and second electrodes 5 formed on the scandium-doped hafnium oxide layer 4. The first electrode 3 further includes a silicon substrate 31, a silica layer 32 formed on the silicon substrate 31, a titanium layer 33 formed on the silica layer 32 and a white gold layer 34 formed on the titanium layer 33, and the second electrodes 5 are white gold.

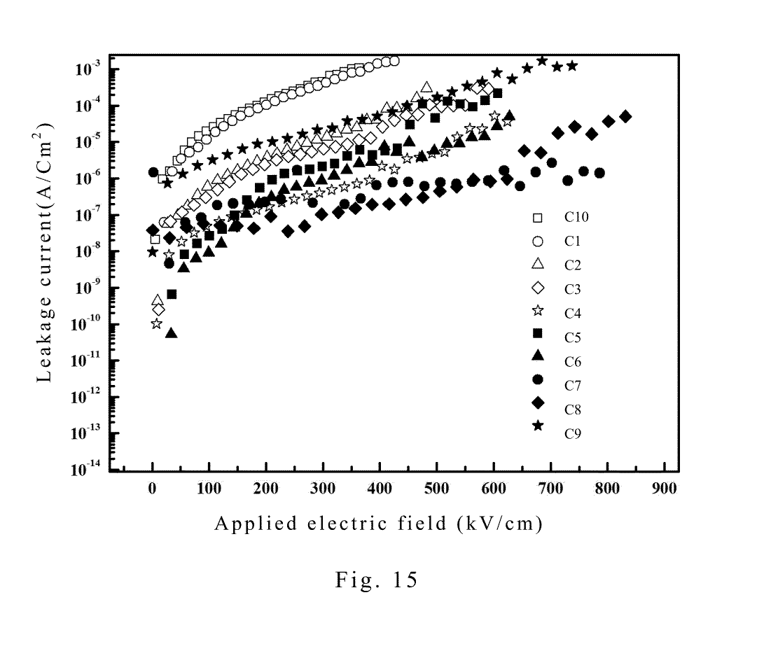

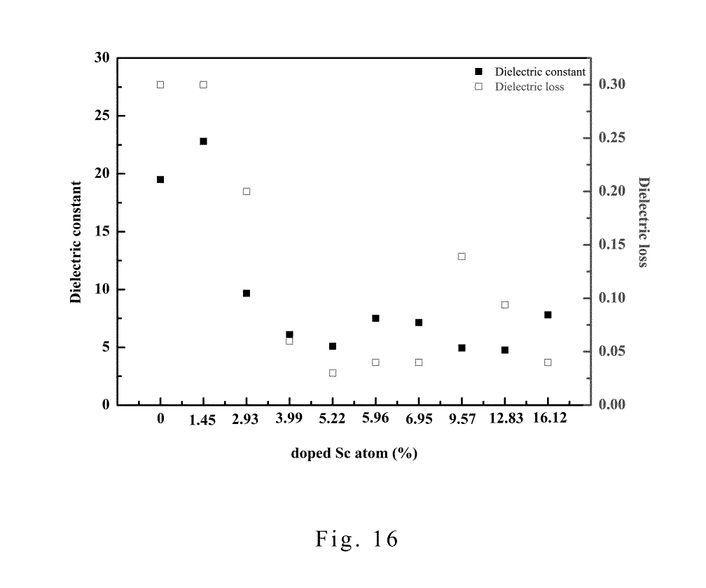

With reference to FIGS. 15-16, which respectively shows the analyzed result of the current leakage, the dielectric constant (K) and the dielectric loss with the different scandium-doped MIM capacitances (C1-9). Further with the reference to Tab. 4 below, Tab. 4 shows the different scandium-doped MIM capacitances and the corresponding thickness of the scandium-doped hafnium oxide layer. Furthermore, a non-scandium-doped MIM capacitance (C10) is prepared to be compared with the capacitances, C1-9, and the thickness of the hafnium oxide layer of the non-scandium-doped MIM capacitance C10 is 274 nm.

| | | Thickness of the |
|---|---|---|
| MIM | | scandium-doped hafnium |
| capacitance | Scandium doping (at %) | oxide film (nm) |
| C1 | 1.45 | 233 |
| C2 | 2.93 | 200 |
| C3 | 3.99 | 169 |
| C4 | 5.22 | 159 |
| C5 | 5.96 | 159 |
| C6 | 6.95 | 159 |
| C7 | 9.57 | 125 |
| C8 | 12.83 | 118 |
| C9 | 16.12 | 133 |

Tab. 4 shows the scandium doping and the thickness of the scandium-doped hafnium oxide layer of the different scandium-doped MIM capacitances.

Referring to FIG. 15, in contrast to the non-scandium-doped MIM capacitance C10, the scandium-doped MIM capacitances C1-9 appear a prevention of current leakage while an electric field (0-800 kV/cm) is applied to the scandium-doped hafnium oxide layer. Tab. 5 shows the analysis under the applied electric field reaching to 100 kV/cm. The value of the current leakage is effectively suppressed even the thickness of the scandium-doped hafnium oxide layer is reduced as shown in FIG. 15 and Tab. 5. Moreover, the scandium-doped MIM capacitance is able to more reduce the current leakage at least two progressions than the non-scandium-doped MIM capacitance C10.

As to the dielectric constant and the dielectric loss of the different scandium-doped MIM capacitances, both values are reduced relatively to the increment of the scandium doping, but the dielectric constant of the capacitance C9 is raised relatively to C8 due to excess scandium doping.

| | | Current leakage | | | |
|---|---|---|---|---|---|
| | | (mA/cm²) under | | | |
| | Scandium | condition where the | | | Thickness of the |
| MIM | doping | applied electric field | dielectric | dielectric | scandium-doped hafnium |
| capacitance | (at %) | is 100 kV/cm | constant | loss | oxide film (nm) |
| C1 | 1.45 | 1.31 × 10⁻⁵ | 22.8 | 0.33 | 233 |
| C2 | 2.93 | 6.37 × 10⁻⁷ | 9.7 | 0.2 | 200 |
| C3 | 3.99 | 3.47 × 10⁻⁷ | 6.1 | 0.06 | 169 |
| C4 | 5.22 | 5.04 × 10⁻⁸ | 5.1 | 0.03 | 159 |
| C5 | 5.96 | 2.56 × 10⁻⁸ | 7.5 | 0.04 | 159 |
| C6 | 6.95 | 9.06 × 10⁻⁹ | 7.1 | 0.04 | 159 |
| C7 | 9.57 | 1.08 × 10⁻⁷ | 4.9 | 0.14 | 125 |
| C8 | 12.83 | 4.10 × 10⁻⁸ | 1.8 | 0.09 | 118 |
| C9 | 16.12 | 2.98 × 10⁻⁶ | 7.8 | 0.04 | 133 |
| C10 | 0 | 2.16 × 10⁻⁵ | 19.6 | 0.31 | 274 |

Tab. 5 shows value of the current leakage, dielectric constant and dielectric loss of the different scandium-doped MIM capacitances C1-9 and the non-scandium-doped MIM capacitance C10.

Accordingly, the scandium-doped hafnium oxide film prepared by the method in accordance with the present invention is able to further reduce electric elements with prevention of the current leakage in the oxide layer of the electric elements. Furthermore, the reduction of the dielectric loss of the oxide layer in the electric element is able to further suppress heat generation in the oxide layer to prevent the electric elements from breaking down.

What is claimed is:

1. A method for preparing scandium-doped hafnium oxide film, comprising:
preparing a hafnium target having scandium granules distributed on a peripheral surface thereof, wherein an area of the scandium granules to a peripheral surface of the hafnium target occupation ratio is 6.90-30.57%; and
proceeding a sputtering process with the hafnium target to form a scandium-doped hafnium oxide film, wherein argon and oxygen are added with a flow rate of 1:1, and pressure in the sputtering process is selectively adjusted to 1×10⁻² and 5×10⁻⁷ torr.

2. A scandium-doped hafnium oxide film as claimed in claim 1 having a scandium doping density of 3-13 at %.
